(19) United States
(12) Patent Application Publication
(10) Pub. No.: US 2009/0051019 A1
(43) Pub. Date: Feb. 26, 2009

(54) Multi-chip module package

(76) Inventors: Chih-Feng Huang, Taipei (TW); Chiu-Chih Chiang, Taipei (TW); You-Kuo Wu, Taipei (TW); Lih-Ming Doong, Taipei (TW)

Correspondence Address: BERLINER & ASSOCIATES, 555 WEST FIFTH STREET, 31ST FLOOR, LOS ANGELES, CA, 90013, US

(21) Appl. No.: 11/894,341

(22) Filed: Aug. 20, 2007

(51) Int. Cl. H01L 23/495; H01L 23/02

(52) U.S. Cl. 257/676; 257/686; 257/E23.079; 257/E23.172

(57) ABSTRACT

A multi-chip module package is provided, which includes a first chip mounted on via a first conductive adhesive and electrically connected to a first chip carrier, a second chip mounted on via a second conductive adhesive and electrically connected to a second chip carrier which is spaced apart from the first chip carrier, wherein the second conductive adhesive is made of an adhesive material the same as that of the first conductive material, a plurality of conductive elements to electrically connect the first chip to the second chip and an encapsulant encapsulating the first chip, the first chip carrier, the second chip, the second chip carrier and the plurality of conductive elements, allowing a portion of both chip carriers to be exposed to the encapsulant, so that the first chip and second chip are able to be insulated by the separation of the first and second chip carriers.

### BACKGROUND OF THE INVENTION

1. Field of the Invention

The present invention relates to multi-chip module packages, and more particularly, to a multi-chip module package that has a switching chip and a driving chip.

2. Description Related Art

A smart power switching (SPS) package is one of various power devices for electronic products, which typically contains a transistor, which is a switching chip, and a control IC, which is a driving chip.

As there are many drawbacks existing in conventional SPS packages, U.S. Pat. No. 6,756,689 proposes a package structure designed for solving the drawbacks of the conventional SPS packages. As shown in FIG. 5, the package structure 5 described in U.S. Pat. No. 6,756,689 has a die pad 50 of a lead frame on which a switching chip 51 and a driving chip 52 are mounted via a conductive adhesive 53 and an insulating adhesive tape 54, respectively.

The package structure 5, however, has a couple of problems. For example, the conductive adhesive 53 has to be cured by a curing process prior to the attachment of the insulating adhesive tape 54 onto the die pad 50, as the conductive adhesive 53 and the insulating adhesive tape 54 are different in material. Accordingly, the process for fabricating the package structure 5 is complicated and fabricating cost is increased. Further, the conductive adhesive 53 differs in material from the insulating adhesive tape 54, whereby there exists CTE (Coefficient of Thermal Expansion) mismatch that causes reliability concern to the package structure 5 due to different thermal stress exerted to the switching chip 51 and the driving chip 52 during subsequent temperature cycles. Moreover, the switching chip 51 and the driving chip 52 are coplanarily mounted on the die pad 50 such that the die pad 50 has to be of a size sufficient to mount the two chips thereon. Nevertheless, the larger the size of the pad 50 is, the bigger the thermal stress resulted from the die pad 50 is. It thus tends to cause delamination of the die pad 50 from an encapsulant 55 used to encapsulate the switching chip 51, the driving chip 52 and the die pad 50 to occur, thereby adversely affecting the reliability of the package structure 5 thus fabricated.

In the '689 patent, another package structure 6 is also provided. As shown in FIG. 6, the package structure 6 is composed of a die pad 60, a switching chip 61 mounted on the die pad 60 via a conductive adhesive 62, a driving chip 63 stacked on the switching chip 61 via an insulating adhesive tape 64, and an encapsulate 65 for encapsulating the die pad 60, the switching chip 61 and the driving chip 63.

The driving chip 63 is stacked on the switching chip 61 such that the die pad 60 employed can be relatively smaller than that employed in the aforementioned package structure 5, and thereby delamination concern can be eliminated. Nevertheless, the conductive adhesive 62 differs in material from the insulating adhesive tape 64, the curing process for curing the conductive adhesive 62 still has to be performed prior to the attachment of the insulating adhesive tape 64 to the switching chip 61. It is well known in the art, the top surface 610 of the switching chip 61 for the insulating adhesive tape 64 to be attached thereonto needs to be cleaned because the top surface 610 is usually contaminated during the curing process. Such a post-treatment process for cleaning the top surface 610 thus increases the complexity of the overall fabrication process and the fabrication cost therefor.

The '689 patent further proposes a package structure 7, as shown in FIG. 7, that a liquid non-conductive adhesive 74 is used to adhere the driving chip 73 to the switching chip 71. However, the liquid non-conductive adhesive 74 and the conductive adhesive 72 are different in material, whereby two independent curing processes are required, thus making the fabrication process complicated and fabrication cost therefore increased. Moreover, as the driving chip 73 is mounted on the switching chip 71 via the liquid non-conductive adhesive 74, chip tilt will likely occur that thus degrades the reliability of the package structure 7.

As a result, there exists a need for improved multi-chip module packages that can effectively eliminate the defects of the prior art structures.

### SUMMARY OF THE INVENTION

The present invention provides a multi-chip module package that the reliability can be ensured due to the use of separate chip carriers and same adhesives for chip mounting, and that the fabrication process can be simplified and the fabricating cost therefor can be decreased owing to the use of same adhesives for chip mounting.

According to a first embodiment of the present invention, a multi-chip module package is provided which includes a first chip mounted on via a first conductive adhesive and electrically connected to a first chips carrier, a second chip mounted on via a second conductive adhesive and electrically connected to a second chip carrier, wherein the first chip carrier is spaced apart from the second chip carrier by a predetermined distance and wherein the first conductive adhesive is made of an adhesive material the same as that of the second conductive adhesive, a plurality of conductive elements for electrically connecting the first chip to the second chip, and an encapsulant for encapsulating the first and second chips, the first and second chips, and the plurality of conductive elements, while allowing a portion of the first chip carrier and a portion of the second chip carrier to be exposed from the encapsulant.

The first and second chip carriers can be either a lead frame or a substrate. And, the first chip can be a switching chip while the second chip can be a driving chip. As to the conductive elements, bonding wires, such as Cu wires or Au wires, are applicable thereto.

According to a second embodiment of the present invention, a multi-chip module package is provided which includes a chip carrier for a first chip to be electrically connected thereto and mounted thereon via a first conductive adhesive, wherein the first chip has an active surface formed with an insulating layer, a second chip electrically connected to the first chip via a plurality of conductive elements and stacked on the first chip via a second conductive adhesive, allowing the insulating layer to be interposed between the second conductive adhesive and the first chip, wherein the second conductive adhesive is made of an adhesive material the same as that of the first conductive adhesive, and an encapsulant for encapsulating the chip carrier, the first and second chips, and the conductive elements, while allowing a portion of the chip carrier to be exposed from the encapsulant.

The insulating layer can be formed by a resist material or a dielectric material such as oxide or nitride or other material that is non-conductive in nature.

According to a third embodiment of the present invention, a multi-chip module package is provided when includes a chip carrier for a first chip to mount thereon via a first conductive adhesive and electrically connect thereto, a second chip stacked on via a second conductive adhesive and electrically connected to the first chip, wherein on a non-active surface of the second chip an insulating layer is formed for allowing the insulating layer to be interposed between the second conductive adhesive and the second chip, and wherein the second conductive adhesive is made of an adhesive material the same as that of the first conductive adhesive, a plurality of conductive elements for electrically connecting the second chip to the first chip, and an encapsulant for encapsulating the first chip, the second chip, the conductive elements, and the chip carrier, while allowing a portion of the chip carrier to be exposed from the encapsulant.

According to a fourth embodiment of the present invention, a multi-chip module package is provided which includes a chip carrier, a first chip mounted on via a first conductive adhesive and electrically connected to the chip carrier, a second chip mounted on via a second conductive adhesive and electrically connected to the chip carrier, wherein on a non-active surface of the second chip an insulating layer is formed for allowing the insulating layer to be interposed between the second conductive adhesive and the second chip, and wherein the second conductive adhesive is made of an adhesive material the same as that of the first conductive adhesive, a plurality of conductive elements for electrically connecting the second chip to the first chip, and an encapsulate for encapsulating the first chip, the second chip, the conductive elements, and the chip carrier, while allowing a portion of the chip carrier to be exposed form the encapsulant.

The formation of the insulating layer as mentioned above can be carried out in the wafer level, which means that the insulating layer is formed on the wafer prior to the singulation of the wafer into a plurality of individual chips.

The first and second conductive adhesives are made of the same material, such that they can be cured by the same curing process. It thus simplifies the fabrication process and reduces the fabrication cost. With the provision of the insulating layer, the insulative of the first and second chips can be secured and, meanwhile, the first conductive adhesive can be the same in material as the second conductive adhesive, allowing CTE mismatch concern to be effectively eliminated as so as to enhance the product reliability and the wiring process to be performed subsequent to the completion of chip stacking so as to decrease the fabrication cost.

### BRIEF DESCRIPTION OF DRAWINGS

The present invention can be made fully understood by reading the following detailed description of the preferred embodiments, with reference made to the accompanying drawings, wherein:

FIG. 1 is a cross-sectional view of a multi-chip module package according to a first preferred embodiment of the present invention;

FIG. 2 is a cross-sectional view of a multi-chip module package according to a second preferred embodiment of the present invention;

FIG. 3 is a cross-sectional view of a multi-chip module package according to a third preferred embodiment of the present invention;

FIG. 4 is a cross-sectional view of a multi-chip module package according to a fourth preferred embodiment of the present invention;

FIG. 5 is a cross-sectional view of a conventional multi-chip module package

FIG. 6 is a cross-sectional view of another conventional multi-chip module package; and

FIG. 7 is a cross-sectional view of a further conventional multi-chip module package.

### DESCRIPTION OF THE PREFERRED EMBODIMENTS

The following illustrative embodiments are provided to illustrate the features, effects, and advantages of the present invention such that they can be apparently understood by those in the art after reading the disclosure of this specification. The present invention can also be performed or applied by after different embodiments. The details of the specification may be on the basis of different points and applications, and numerous modifications and variation can be devised without departing from the spirit of the present invention.

### First Embodiment

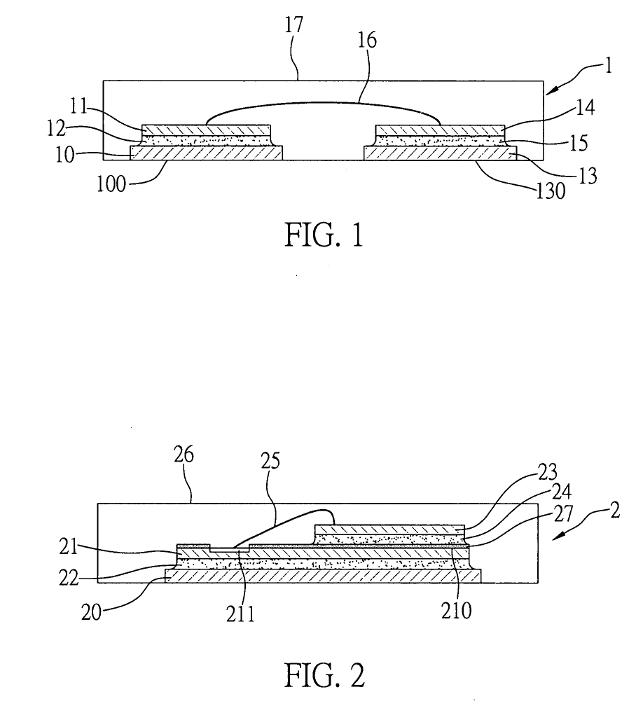

Referring to FIG. 1, a cross-sectional view of the multi-chip module package according to the first embodiment of the present invention is shown. As shown in the drawing, the multi-chip module package 1 is composed of a first die pad 10 of a lead frame (merely the die pad 10 of the lead frame is shown for the sake of simplification), a switching chip 11 mounted on via a first conductive adhesive 12 and electrically connected to the first die pad 10, a second die pad 13 of the lead frame (not shown) spaced apart from the first die pad 10 by a predetermined distance, a driving chip 14 mounted on via a second conductive adhesive 15 and electrically connected to the second die pad 13, a plurality of bonding wires 16 for electrically connecting the switching chip 11 to the driving chip 14, and an encapsulant 17 for encapsulating the first and second die pads 10 and 13, the switching chip 11, the driving chip 4, and the plurality of bonding wires 16, while allowing a bottom surface 100 of the first die pad 10 and a bottom surface 130 of the second die pad 13 to be exposed from the encapsulant 17.

As the first die pad 10 is spaced apart from the second die pad 13, the first and second die pads 10 and 13 are small in dimension such that the thermal stress exerted thereto is reduced during subsequent temperature cycles and delamination of the first and second die pads 10 and 13 from the encapsulant 17 can be effectively prevented. Consequently, the reliability of the multi-chip module package 1 can be improved.

Further, as the insulation of the switching chip 11 and the driving chip 14 can be accomplished by the separation of the first die pad 10 and the second die pad 13, a mere single curing process is required for curing the first and second conductive adhesives 12 and 15 in that the first and second conductive adhesives 12 and 15 are made of the same adhesive material, such as silver paste or solder. Accordingly, the first and second conductive adhesives 12 and 15 can be applied onto the corresponding first and second die pads 10 and 13 at the same time. This solves the problem of the prior art package mentioned in the above that the conductive adhesive needs to be applied onto the die pad and cured prior to the attachment of the insulating adhesive tape to the die pad. As a result, the fabrication process for the multi-chip module package 1 is simpler than the aforementioned prior art and the fabrication cost can be reduced. In addition, in the prior art as discussed, the curing process needs to be performed prior to the adhesion of the insulating adhesive tape to the predetermined area of the die pad such that the predetermined area is usually contaminated during the curing process and required to be cleaned after the curing process is completed and before the insulating adhesive tape, such as polyamide tape, is to be attached to the predetermined area of the die pad. By contrast, no post-treatment process is required for the multi-chip module package 1 of the first embodiment of the present invention as the curing process is performed after the die bond process is completed, thereby making the second die pad 13 free of contamination concern. That thus further simplifies the fabrication process and reduces the fabrication cost.

The electrical connections of the switching chip 11 and the first die pad 10 as well as the driving chip 14 and the second die pad 13 can be achieved by bonding wires such as gold wires or copper wires. For purpose of simplification in illustration, the bonding wires are not shown in the drawings; and the wire bonding process is also conventional so that the illustration is omitted herein.

The formation of the encapsulant 17 can be achieved by conventional molding process such that detailed description thereto is similarly omitted.

### Second Embodiment

Referring to FIG. 2, a cross-sectional vies of a multi-chip module package according to the second embodiment of the present invention is shown.

As shown in the drawing, the multi-chip module package 2 of the second embodiment has a die pad 20 of a lead frame (not shown) for a switching chip 21 to be mounted thereon via a first conductive adhesive 22 and electrically connected thereto via a plurality of bonding wires (not shown). A driving chip 23 is then stacked on the switching chip 21 via a second conductive adhesive 24 and electrically connected to the switching chip 21 via a plurality of bonding wires 25. And, an encapsulant 26 is formed to encapsulate the die pad 20, the switching chip 21, the driving chip 23 and the bonding wires 25, but allowing a bottom surface (not shown) of the die pad 20 to be exposed from the encapsulant 26.

To secure the insulation of the switching chip 21 and the driving chip 23, on an active surface 210 of the switching chip 21 an insulating layer 27 is formed. The insulating layer 27 may be a dielectric layer made of oxide or nitride or a resist layer, and can be formed on a wafer for being sawed into individual switching chips 21. By the formation of the insulating layer 27, the driving chip 23 can be insulated from the switching chip 21, thereby allowing the second conductive adhesive 24 to be the same in material as the first conductive adhesive 22. As the first and second conductive adhesives 22 and 24 are the same in adhesive material, the curing process can be performed subsequent to the die bond of the driving chip 23 such that the insulating layer 27 is not contaminated during the curing process and allows the second conductive adhesive 24 to be applied thereonto without reliability concern.

Further, the electrical connection quality between the switching chip 21 and the driving chip 23 via the wires 25 can be secured due to the fact that the bond pads 211, formed on the active surface 210 of the switching chip 21 and exposed from the insulating layer 27, are free from contamination for the reason that the curing process is performed after the die bonding process and the wire bonding process have been completed.

### Third Embodiment

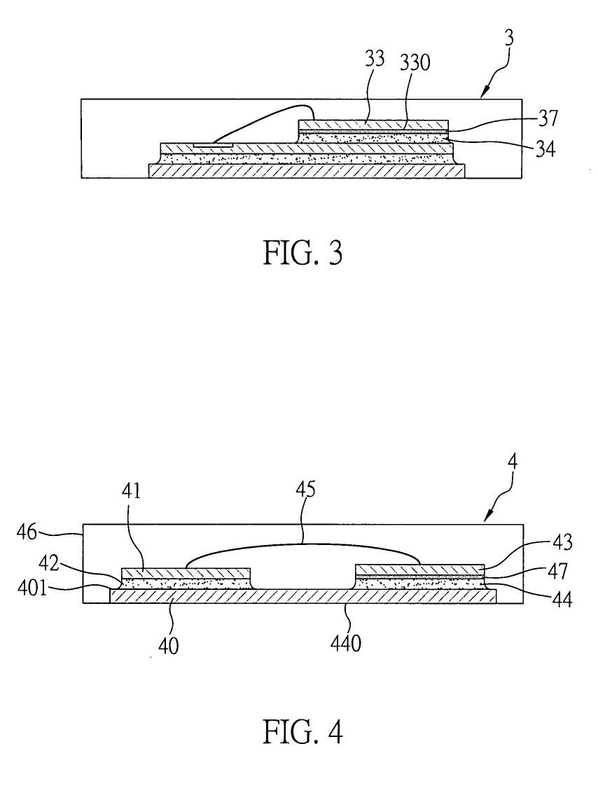

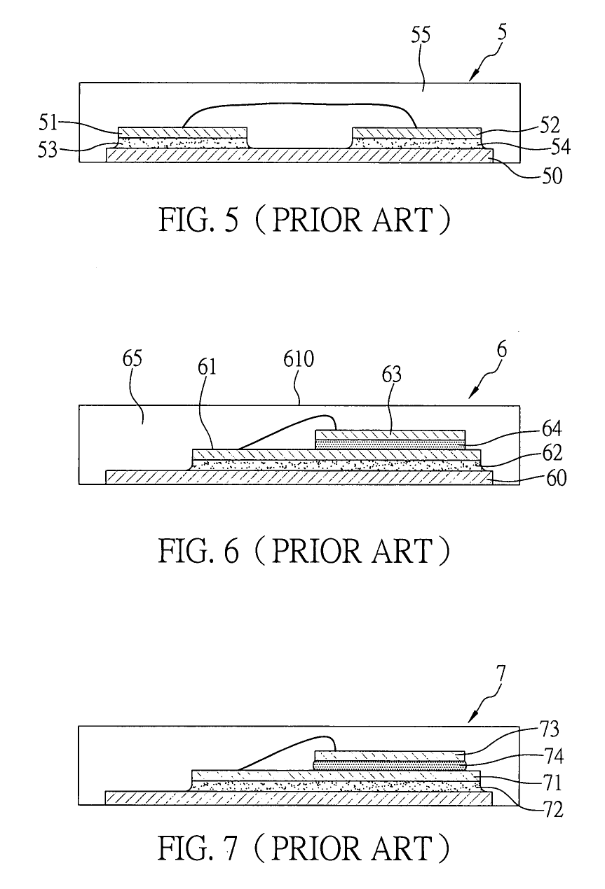

Referring to FIG. 3, a cross-sectional view of a multi-chip module package according to a third embodiment of the present invention is shown.

As shown in the drawing, the multi-chip module package 3 of the third embodiment of the present invention is essentially similar in structure to the package 2 of the second embodiment described above, except that an insulating layer 37 is formed on a non-active surface 330 of the driving chip 33, allowing the insulating layer 37 to be interposed between the second conductive adhesive 34 and the driving chip 33. The insulating layer 37 can be formed on a bottom surface of a wafer (not shown) for being sawed into individual driving chip 33 whereby there will be no additional formation process for the assembly of the multi-chip module package 3.

### Fourth Embodiment

Referring to FIG. 3, a cross-sectional view of a multi-chip module package according to a fourth embodiment of the present invention is shown.

As shown in the drawing, the multi-chip module package 4 of the fourth embodiment has a die pad 40 of a lead frame (not shown) for a switching chip 41 and a driving chip 43 mounted thereon via a first conductive adhesive 42 and a second conductive adhesive 44, respectively. Both the switching chip 41 and the driving chip 43 can be electrically connected to the die pad 40 via a plurality of bonding wires (not shown). The driving chip 43 is further formed with an insulating layer 47 on a non-active surface thereof for securing the insulation of the switching chip 41 and the driving chip 43 and allowing the first and second conductive adhesives 42 and 44 to be made of same adhesive material. A plurality of bonding wires 45 are employed to electrically connect switching chip 41 to the driving chip 43 and an encapsulant 46 is formed to encapsulate the die pad 40, the switching chip 41, the driving chip 43, and the bonding wires 45 with a bottom surface 440 of the die pad 40 being exposed from the encapsulant 46.

It is thus to be understood that, being made of the same material, the first and second conductive adhesives 42 and 44 can be applied onto an top surface 401 of the die pad 40 at the same time and allow merely a curing process to be performed after the die bonding of the switching chip 41 and the driving chip 43 is completed. Accordingly, the multi-chip module package 4 of the present invention is simpler in fabrication process than the corresponding prior art structure discussed in the above. And, the reliability of the multi-chip module package 4 can be enhanced as the predetermined area of the top surface 401 of the die pad 40 is free from contamination in that the curing process is allowed to be performed subsequent to the die bonding process and the wire boding process.

The foregoing descriptions of the embodiments of the invention have been presented for the purposes of illustration and description. They are not intended to be exhaustive or to limit the invention to the precise forms disclosed. Persons skilled in the relevant art can appreciate that many modifications and variations are possible in light of the above teaching. It is therefore intended that the scope of the invention be limited not by this detailed description, but rather by the claims appended hereto.

What is claimed is:

1. A multi-chip module package, comprising:
a first chip mounted on via a first conductive adhesive and electrically connected to a first chip carrier;
a second chip mounted on via a second conductive adhesive and electrically connected to a second chip carrier, wherein the second chip carrier is spaced apart from the first chip carrier, and the second conductive adhesive is made of an adhesive material the same as that of the first conductive material;
a plurality of conductive elements for electrically connecting the first chip to the second chip; and
an encapsulant encapsulating the first chip, the first chip carrier, the second chip, the second chip carrier and the plurality of conductive elements, allowing a portion of the first chip carrier and a portion of the second chip carrier to be exposed to the encapsulant.

2. The multi-chip module package as claimed in claim 1, wherein the first chip carrier and second chip carrier are lead frames each having a die pad for the first and second chips to be mounted thereon.

3. The multi-chip module package as claimed in claim 1, wherein the conductive elements are bonding wires.

4. The multi-chip module package as claimed in claim 1, wherein the first and second conductive adhesives are silver paste.

5. The multi-chip module package as claimed in claim 1, wherein the first chip is a switching chip and the second chip is a driving chip.

6. The multi-chip module package as claimed in claim 1, wherein the first chip is a driving chip and the second chip is a switching chip.

7. A multi-chip module package, comprising:
a chip carrier;
a first chip mounted on via a first conductive adhesive and electrically connected to the chip carrier;
a second chip stacked on via a second conductive adhesive and electrically connected to the first chip, wherein the first conductive adhesive is made of an adhesive material substantially the same as that of the second conductive adhesive;
an insulating layer formed on the first chip such that the insulating layer is interposed between the first chip and the second conductive adhesive to allow the second chip to be insulated from the first chip;
a plurality of conductive elements for electrically connecting the first chip to the second chip; and
an encapsulant for encapsulating the first chip, the second chip, the chip carrier and the plurality of conductive elements, allowing a portion of the chip carrier to be exposed from the encapsulant.

8. The multi-chip module package as claimed in claim 7, wherein the insulating layer is a dielectric layer or a solder layer.

9. The multi-chip module package as claimed in claim 7, wherein the insulating layer is formed by a material of oxide or nitride.

10. The multi-chip module package as claimed in claim 7, wherein the insulating layer is formed on a wafer for forming the first chip.

11. The multi-chip module package as claimed in claim 7, wherein the conductive elements are bonding wires.

12. The multi-chip module package as claimed in claim 7, wherein the first and second conductive adhesives are silver paste.

13. A multi-chip module package, comprising:
a chip carrier;
a first chip mounted on via a first conductive adhesive and electrically connected to the chip carrier;
a second chip stacked on the first chip via a second conductive adhesive, wherein the second conductive adhesive is made of a material substantially the same as that of the first conductive adhesive;
an insulating layer formed on the second chip in a manner that the insulating layer is interposed between the second chip and the second conductive adhesive, for allowing the second chip to be insulated from the first chip;
a plurality of conductive elements for electrically connecting the first chip to the second chip; and
an encapsulant encapsulating the first and second chips, the chip carrier, and the plurality of conductive elements, allowing a portion of the chip carrier to be exposed from the encapsulant.

14. The multi-chip module package as claimed in claim 13, wherein the insulating layer is a dielectric layer or a solder layer.

15. The multi-chip module package as claimed in claim 13, wherein the insulating layer is formed by a material of oxide or nitride.

16. The multi-chip module package as claimed in claim 13, wherein the insulating layer is formed on a wafer for forming the second chip.

17. The multi-chip module package as claimed in claim 13, wherein the conductive elements are bonding wires.

18. The multi-chip module package as claimed in claim 13, wherein the first and second conductive adhesives are silver paste.

19. A multi-chip module package, comprising:
a chip carrier;
a first chip mounted on via a first conductive adhesive and electrically connected to the chip carrier;
a second chip mounted on via a second conductive adhesive and electrically connected to the chip carrier, wherein the first conductive adhesive is made of an adhesive material substantially the same as that of the second conductive adhesive;
an insulating layer formed on the second chip in a manner that, the insulating layer is interposed between the second chip and the second conductive adhesive, for allowing the second chip to be insulated from the first chip;
a plurality of conductive elements for electrically connecting the first chip to the second chip; and
an encapsulant for encapsulating the first and second chips, the chip carrier, and the plurality of conductive elements, allowing a portion of the chip carrier to be exposed from the encapsulant.

20. The multi-chip module package as claimed in claim 19, wherein the insulating layer is a dielectric layer or a solder layer.

21. The multi-chip module package as claimed in claim 19, wherein the insulating layer is formed by a material of oxide or nitride.

22. The multi-chip module package as claimed in claim 19, wherein the insulating layer is formed on a wafer for forming the second chip.

23. The multi-chip module package as claimed in claim 19, wherein the conductive elements are bonding wires.

24. The multi-chip module package as claimed in claim 19, wherein the first and second conductive adhesives are silver paste.
